(19) United States
(12) Patent Application Publication
(10) Pub. No.: US 2008/0001222 A1
(43) Pub. Date: Jan. 3, 2008

(54) Semiconductor Device Of High Breakdown Voltage And Manufacturing Method Thereof

(76) Inventor: Tae-Pok Rhee, Suwon-si (KR)

Correspondence Address: IPLA P.A., 3580 WILSHIRE BLVD., 17TH FLOOR, LOS ANGELES, CA, 90010, US

(21) Appl. No.: 11/568,438

(22) PCT Filed: Apr. 27, 2005
(86) PCT No.: PCT/KR05/01211

§ 371 Date: Oct. 27, 2006

(30) Foreign Application Priority Data
Apr. 27, 2004 (KR) 10-2004-0029113

(51) Int. Cl. H01L 23/62; H01L 21/336

(52) U.S. Cl. 257/339; 438/282; 257/E29.141; 257/E21.409

(57) ABSTRACT

Disclosed are a high breakdown voltage semiconductor device and a method of manufacturing the same. According to the invention, an insulation spacer capable of substitute-performing functions of an inter-insulation film, a contact hole and a mask, etc. by a self-alignment and simplifying a general process for manufacturing a device is newly arranged in a part of a gate electrode pattern. Thus, it is possible to naturally reduce the number of masks required for the device manufacture. Accordingly, a manufacturer can easily avoid various problems caused due to an increase of the number of masks. Further, it is possible to minimize a morphology abnormality of each unit patterns due to a miss-alignment of the mask and to effectively reduce a size of the device to be finally completed.

### TECHNICAL FIELD

The present invention relates to a high breakdown voltage semiconductor device. More particularly, the present invention relates to a high breakdown voltage semiconductor device wherein an insulation spacer capable of substitute-performing functions of an inter-insulation film, a contact hole and a mask, etc. by a self-alignment and simplifying a general process for manufacturing a device is newly arranged in a part of a gate electrode pattern. Thus, it is possible to naturally reduce the number of masks required for the device manufacture. It allows a manufacturer to easily avoid various problems caused due to an increase of the number of masks, for example, an increase of manufacturing cost, an extension of a manufacturing period, an increase of a burden of stored goods (physical distribution), a falling off in cost competitiveness, and an extension of a product development period, etc. In addition, the invention relates to a method of manufacturing the high breakdown voltage semiconductor device.

### BACKGROUND ART

In recent years, as various kinds of electronics such as a liquid crystal display and a plasma display panel are developed and popularized, a demand for a high breakdown voltage semiconductor device which should be connected and operated to various peripheral device equipped to the electronics is also drastically increasing.

As shown in FIG. 1, in a high breakdown voltage semiconductor device 10 according to the prior art, a semiconductor substrate 1 is separated into a device separating area and an active area by a device separating film 5. In this case, the semiconductor device 1 comprises, for example, a high concentration impurity layer 1a and a high breakdown voltage epitaxial layer 1b.

Under such structure, the active area of the semiconductor substrate 1 is sequentially provided with a gate electrode pattern 7, a gate insulating film pattern 6, a channel diffusion layer 2, a source diffusion layer 4, a resistance drop-inducing layer 3, an inter-insulation film 8 and a metal electrode 9, etc. In this case, the channel diffusion layer 2 consists of, for example, a low concentration of P-type impurities. The source diffusion layer 4 consists of a high concentration of N-type impurities. The resistance drop-inducing layer 3 consists of a high concentration of P-type impurities.

At least 5˜7 masks are typically required to manufacture the high breakdown voltage semiconductor device having the above-mentioned structure. For example, in order to manufacture the high breakdown voltage semiconductor device 10 as shown in FIG. 1, it is required five masks, i.e., one mask in a process of forming the gate electrode pattern 7, one mask in a process of separately forming the source diffusion layer 4, one mask in a process of forming the resistance drop-inducing layer 3, one mask in a process of forming a contact hole of the inter-insulation film 8 and one mask in a process of the metal electrode 9.

Needless to say, it is required additional time and costs to use each masks. If a special measure capable of notably reducing the number of the masks is not taken, a manufacturer cannot help submitting to various problems, such as an increase of manufacturing cost, an extension of a manufacturing period, an increase of a burden of stored goods (physical distribution), a falling off in cost competitiveness, and an extension of a product development period, etc.

Under the mask using system as described above, a series of photograph etching processes using a photoresist pattern and ultraviolet rays, etc. should be inevitably performed so as to normally form the gate insulation film pattern 7, the source diffusion layer 4, the resistance drop-inducing layer 3, the contact hole and the metal electrode 9, etc. It should precede an operation of elaborately aligning the photoresist pattern and the mask so as to normally progress the photograph etching process.

However, since the alignment operation is generally performed in conjunction with various elements such as a stepper, there is a limit to the 100% precise alignment of the photoresist pattern and the mask. Accordingly, if a separate measure is not taken, there inevitably occurs a minute miss-alignment between the photoresist pattern and the mask.

The miss-alignment continues to exert a bad influence on the normal formation of the various device patterns as mentioned above. Accordingly, it cannot be avoided that the device to be finally completed has an increased size larger than an originally designed size. The problem of the size increase becomes worse as the photograph etching process is repeated (i.e., as the required number of the masks is increased).

### DISCLOSURE OF INVENTION

Accordingly, the present invention has been made to solve the above-mentioned problems occurring in the prior art. The object of the present invention is to newly arrange an insulation spacer capable of substitute-performing functions of an inter-insulation layer, a contact hole and a mask, etc. by a self-alignment and simplifying a general process for manufacturing a device in a part of a gate electrode pattern. Thus, the number of masks required for the device manufacture can be naturally reduced. It allows a manufacturer to easily avoid various problems caused due to an increase of the number of masks, for example, an increase of manufacturing cost, an extension of a manufacturing period, an increase of a burden of stored goods (physical distribution), a falling off in cost competitiveness, and an extension of a product development period, etc.

Another object of the invention is to newly arrange an insulation spacer capable of substitute-performing functions of an inter-insulation film, a contact hole and a mask, etc. by a self-alignment, thereby naturally reducing the number of masks required for a device manufacture, minimizing a morphology abnormality of each unit patterns due to a miss-alignment of the mask and effectively reducing a size of the device to be finally completed.

In order to achieve the above objects, there is provided a high breakdown voltage semiconductor device comprising gate electrode patterns individually spacedly formed in an active area of a semiconductor substrate; a channel diffusion layer selectively occupying a part under the space between the gate electrode patterns; source diffusion layers located in both sides of each gate electrode patterns and spacedly formed in a pair in the channel diffusion layer; a resistance drop-inducing layer electrically contacting to each pair of the source diffusion layers located in the channel diffusion layer and selectively arranged in the channel diffusion layer; insulation spacers selectively covering both side walls of each gate electrode patterns so as to allow a part of the source diffusion layer and a part of the resistance drop-inducing layer to be selectively exposed and protruding from each of the gate electrode patterns upward; and a metal electrode occupying an upper part of the semiconductor substrate so as to allow each insulation spacers to be exposed, electrically contacting to the source diffusion layer and the resistance drop-inducing layer exposed by the insulation spacer, and electrically divided by the insulation spacers.

In another aspect, in order to achieve the above-mentioned objects, there is provided a method of manufacturing a high breakdown voltage semiconductor device comprising steps of sequentially depositing a raw material layer of a gate electrode pattern and a sacrificial film on a front surface of a semiconductor substrate having an active area defined, and selectively patterning the raw material layer of the gate electrode pattern and the sacrificial film to form a plurality of gate electrode pattern/sacrificial film pattern deposits individually spaced in the active area; selectively ion-implanting first conductive impurities in the active area to form a channel diffusion layer in a part under the space between the gate electrode pattern/sacrificial film pattern deposits; selectively ion-implanting second conductive impurities in both sides of the gate electrode pattern/sacrificial film pattern deposits to form a pair of source diffusion layers spaced in the channel diffusion layer; forming insulation spacers on both side walls of the gate electrode pattern/sacrificial film pattern deposits so as to allow the channel diffusion layer and the source diffusion layers to be selectively exposed; selectively removing the sacrificial film pattern from the gate electrode pattern/sacrificial film pattern deposits so as to allow the insulation spacers to protrude from the gate electrode pattern upward; selectively ion-implanting the first conductive impurities using the insulation spacers as a mask to form a resistance drop-inducing layer electrically contacting to the source diffusion layers and located in the channel diffusion layer; and forming a metal electrode, which is electrically divided by the insulation spacers and electrically contacts to the source diffusion layer and the resistance drop-inducing layer, on an upper part of the semiconductor substrate.

### BRIEF DESCRIPTION OF DRAWINGS

The above and other objects, features and advantages of the present invention will be more apparent from the following detailed description taken in conjunction with the accompanying drawings, in which:

FIG. 1 an exemplary view of a high breakdown voltage semiconductor device according to the prior art;

FIG. 2 is an exemplary view of a high breakdown voltage semiconductor device according to an embodiment of the invention;

FIGS. 3 to 10 are process flow views sequentially illustrating a method of manufacturing a high breakdown voltage semiconductor device according to an embodiment of the invention;

FIG. 11 is an exemplary view of a high breakdown voltage semiconductor device according to another embodiment of the invention;

FIGS. 12 to 16 are process flow views sequentially illustrating a method of manufacturing a high breakdown voltage semiconductor device according to another embodiment of the invention;

FIGS. 17, 25, 30 and 36 are exemplary views of a high breakdown voltage semiconductor device according to still another embodiment of the invention; and

FIGS. 18 to 24, 26 to 29, 31 to 35 and 37 to 42 are process flow views sequentially illustrating a method of manufacturing a high breakdown voltage semiconductor device according to still another embodiment of the invention.

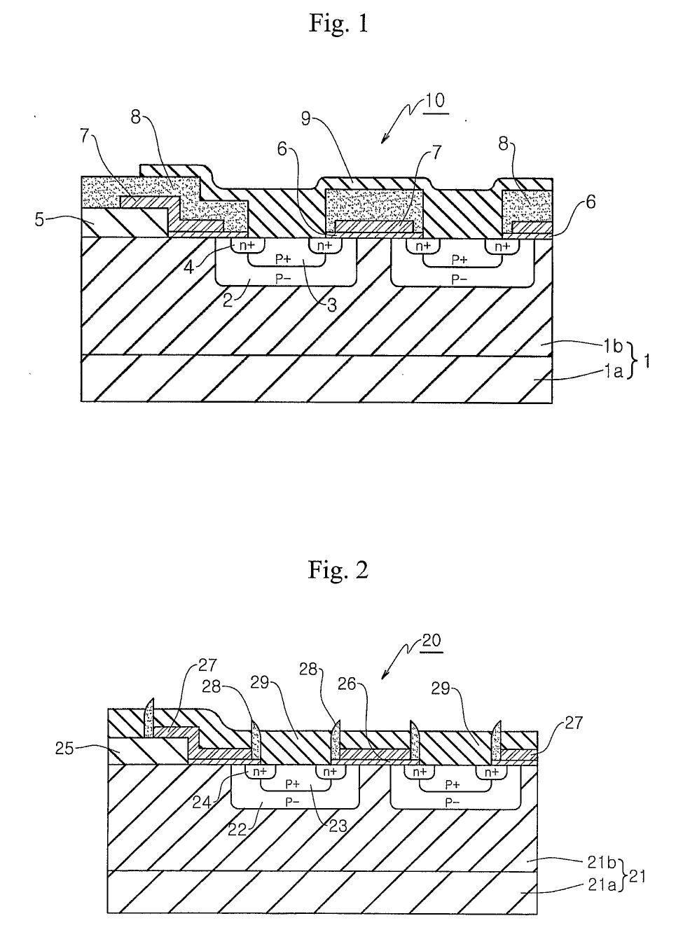

### BEST MODE FOR CARRYING OUT THE INVENTION

Hereinafter, preferred embodiments of the present invention will be described with reference to the accompanying drawings. In the following description of the present invention, a detailed description of known functions and configurations incorporated herein will be omitted when it may make the subject matter of the present invention rather unclear.

As shown in FIG. 2, in a high breakdown voltage semiconductor device 20 according to an embodiment of the invention, a semiconductor substrate 21 is separated into a device separating area and an active area. In this case, the semiconductor substrate 21 comprises, for example, a high concentration impurity layer 21a and a high breakdown voltage epitaxial layer 21b.

Under such structure, the active area of the semiconductor substrate 21 is sequentially provided with gate electrode patterns 27 individually spacedly formed, gate insulating film patterns 26 for electrically insulating the gate electrode patterns 27 from the semiconductor substrate 21, and channel diffusion layers 22, source diffusion layers 24 and resistance drop-inducing layers 23 under a bottom of the gate insulating film patterns 26, which layers are formed by an ion implantation.

In this case, the channel diffusion layer 22 consists of a low concentration of first conductive impurities, for example P-type impurities. The source diffusion layer 24 consists of a high concentration of second conductive impurities, for example N-type impurities. The resistance drop-inducing layer 23 consists of a high concentration of first conductive impurities, for example P-type impurities. The conductive types of the impurities constituting each of the diffusion layers may be variously changed according to the conditions.

At this time, as shown in FIG. 2, the channel diffusion layer 22 selectively occupies a part under the space between the gate electrode patterns 27. The source diffusion layers 24 are positioned at both sides of each gate electrode patterns 27 and spacedly arranged while forming a pair in the channel diffusion layer 22. The resistance drop-inducing layer 23 is selectively positioned in the channel diffusion layer 22 while electrically contacting to the source diffusion layers 24 arranged in the each of the channel diffusion layers 22. With the structure, the resistance drop-inducing layer 23 flexibly performs functions of dropping a resistance of a metal electrode 29 electrically contacting to the resistance drop-inducing layer and inducing smooth operating characteristics to be shown when the device performs an off operation.

In the high breakdown voltage semiconductor device 20 having the above-mentioned structure, as shown in FIG. 2, insulation spacers 28, which protrude from the gate electrode patterns 27 upward while selectively covering both side walls of each of the gate electrode patterns 27 so that parts of the source diffusion layer 24 and the resistance drop-inducing layer 23 are selectively exposed, are additionally arranged an upper part of the semiconductor substrate 21. In this case, the insulation spacer 28 is made of an oxide film, for example.

Since the insulation spacer 28 is formed through a process not requiring a separate mask, for example, an oxide film deposition process and an anisotropic etching process for the oxide film, etc., a manufacturer can easily avoid an additional defrayment of the mask under the use circumstances of the insulation spacer 28.

Each of the insulation spacers 28 selectively exposes the upper part of the semiconductor substrate 21 by a self-alignment manner on which the resistance drop-inducing layer 23 is formed. Thus, the manufacturer can normally form the resistance drop-inducing layer 23 which electrically contacts to each pair of the source diffusion layers 24 arranged in each of the channel diffusion layers 22 and is selectively positioned in the channel diffusion layer 22, without additionally using a separate mask for a selective ion implantation for the resistance drop-inducing layer 23. Thus, according to the invention, the manufacture can effectively eliminate a necessity of the mask for forming the resistance drop-inducing layer 23.

In addition, the insulation spacer 28 selectively opens the source diffusion layer 24 and the resistance drop-inducing layer 23, except an area for forming the gate electrode pattern 27, by a self-alignment manner, similarly to the existing contact hole. Thus, the manufacturer can electrically connect the metal electrode 29 to the source diffusion layer 24 and the resistance drop-inducing layer 23 normally, without additionally using a separate mask for forming the contact hole. Thus, according to the invention, the manufacturer can effectively remove a necessity of the mask for forming the contact hole.

Further, the insulation spacer 28 is protruded from the gate electrode pattern 27 upward and electrically divides the metal electrode 29 like as individual pattern structures. Thus, the manufacturer can normally form the patterned metal electrode 29 without additionally using a separate mask for forming the metal electrode 29. Thus, according to the invention, the manufacturer can effectively remove a necessity of the mask for patterning the metal electrode 29.

As described above, according to the invention, the insulation spacer 28 capable of substitute-performing functions of an inter-insulation layer, a contact hole and a mask, etc. by a self-alignment and simplifying a general process for manufacturing a device is newly arranged in a part of a gate electrode pattern. Thus, it is possible to naturally reduce the number of masks required for the device manufacture. As a result of that, a manufacturer can easily avoid various problems caused due to an increase of the number of masks, for example, an increase of manufacturing cost, an extension of a manufacturing period, an increase of a burden of stored goods (physical distribution), a falling off in cost competitiveness, and an extension of a product development period, etc.

In addition, when the number of the masks required for a device manufacture is substantially reduced by providing the insulation spacer 28 newly, a morphology abnormality of each unit patterns due to a miss-alignment of the mask can be naturally prevented. Accordingly, it is possible to effectively maintain a size of the device to be finally completed to a minimal size.

Hereinafter, a method of manufacturing a high breakdown voltage semiconductor device according to the invention will be specifically described.

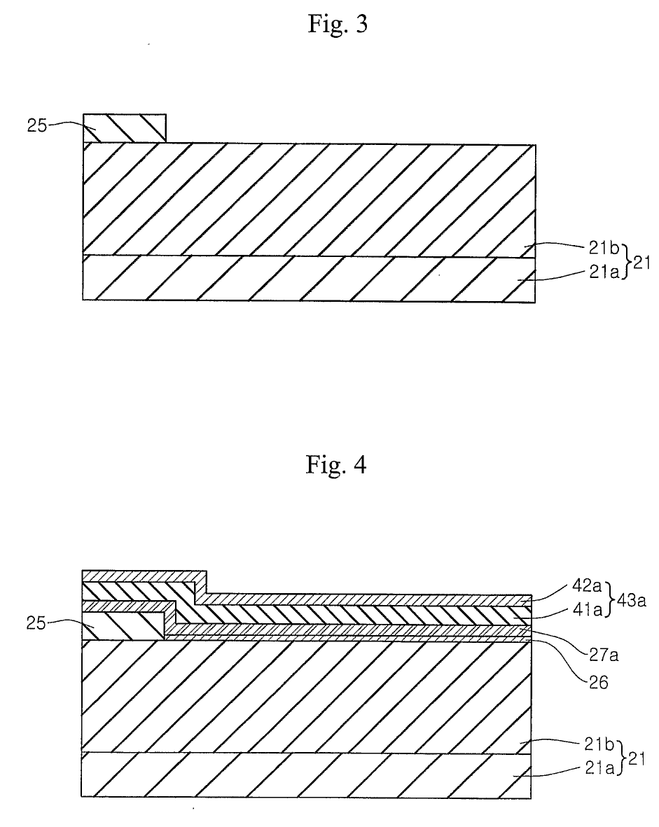

As shown in FIG. 3, according to the invention, a high concentration impurity layer 21a implanted with a high concentration of P-type impurities or N-type impurities is firstly formed. Then, a high breakdown voltage epitaxial layer 21b is formed to have a thickness of several μm˜several tens μm on an upper part of the impurity layer 21a.

Subsequently, according to the invention, a device separating film 25 is formed to have a thickness of 5,000 Å˜15,000 Å through a series of deposition processes and patterning processes, so as to define an active area on the semiconductor substrate 21, for example, an upper part of the high breakdown voltage epitaxial layer 21b. In this case, the device separating film 25 is made of SiO₂, for example.

Then, according to the invention, as shown in FIG. 4, a gate insulating film 26 having a thickness of, for example, 500 Å˜1,500 Å is grown on the active area of the semiconductor substrate 21 through a series of thermal oxidation processes.

Then, according to the invention, a raw material layer 27a of a gate electrode pattern having a thickness of, for example, 4,000 Å˜8,000 Å is formed on the gate insulating film 26 through a series of deposition processes. Then, a sacrificial film 43a having a thickness of 5,000 Å˜30,000 Å is further formed on the raw material layer 27a of the gate electrode pattern. In this case, the sacrificial film 43a comprises a nitride film 41a having a thickness of, for example, 2,000 Å˜30,000 Å and an oxide film 42a having a thickness of, for example, 3,000 Å˜30,000 Å. Of course, the thickness and the material of the sacrificial film 43a may be variously changed according to the conditions.

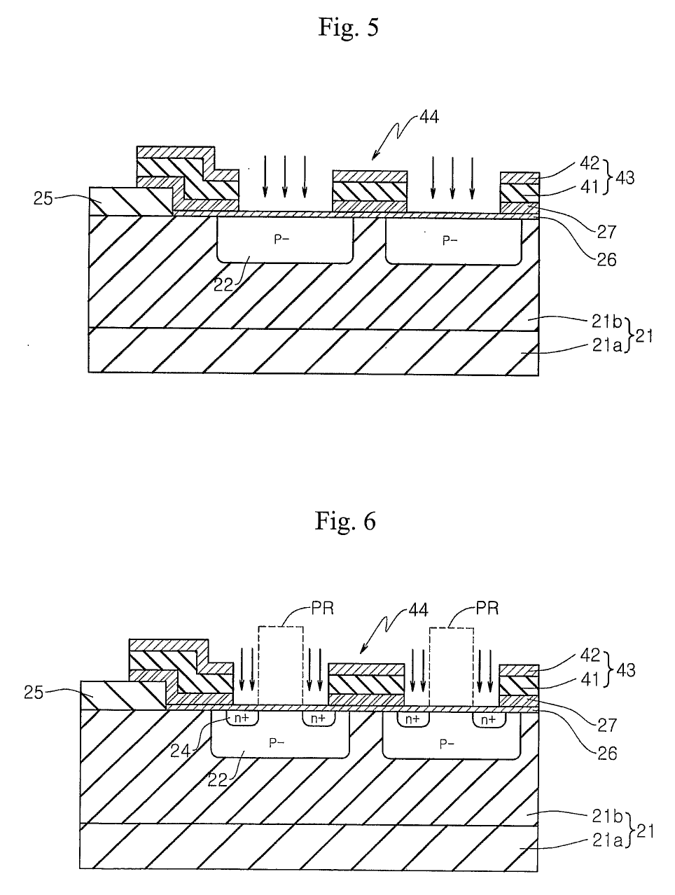

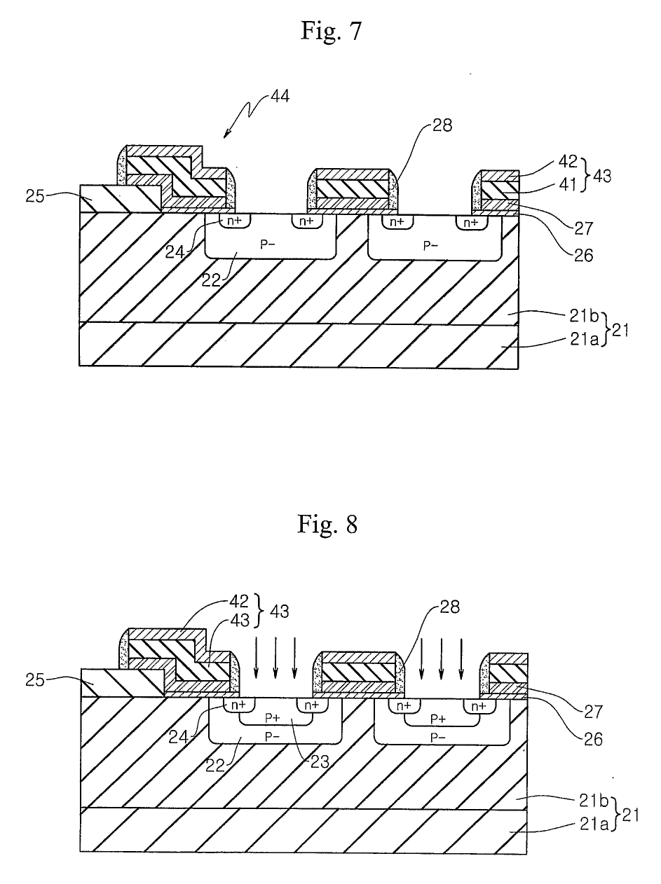

Subsequently, as shown in FIG. 5, the raw material layer 27a of the gate electrode pattern and the sacrificial film 43a are selectively patterned through a series of photograph etching processes using a photoresist pattern (not shown), thereby forming a plurality of gate electrode pattern/sacrificial film deposits 44 on the gate insulating film 26, which are positioned and individually spaced in the active area. One mask is required to perform the process of forming the gate electrode pattern/sacrificial film deposits 44.

When the formation of the gate electrode pattern/sacrificial film deposits 44 on the gate insulating film 26 is completed through the above-mentioned processes, a low concentration of impurities, for example, a low concentration of P-type impurities are ion-implanted and then driven-in for 30 minutes˜600 minutes under circumstances of 1,000° C.˜1,250° C., thereby forming a channel diffusion layer 22 in a part under the space between the gate electrode pattern/sacrificial film deposits 44.

Then, as shown in FIG. 6, a photoresist pattern (PR) for forming a source diffusion layer 24 on the channel diffusion layer 22 is formed through a series of photoresist patterning processes. Then, a high concentration of impurities, for example, a high concentration of N-type impurities having a dosage of about 4.9E15(atoms/cm²)˜5.1E15(atoms/cm²) are selectively ion-implanted with 75 KeV˜85 KeV on both sides of the gate electrode pattern/sacrificial film deposits 44 exposed by the photoresist pattern (PR), thereby forming the source diffusion layers 24 which are spacedly formed with a pair in the channel diffusion layer 22. After that, the photoresist pattern (PR) is removed. One mask is also required to form the source diffusion layers 24.

Subsequently, an insulation film, for example, an oxide film having a thickness of 2,000 Å˜14,000 Å is deposited on the semiconductor substrate 21 comprising the gate electrode pattern/sacrificial film pattern deposits 44 through a series of deposition processes. Then, the oxide film is anisotropically etched, thereby forming insulation spacers 28 on both side walls of each gate electrode pattern/sacrificial pattern deposits 44. In this case, the insulation spacer 28 preferably maintains its thickness of 1,000 Å˜12,000 Å.

When forming the insulation spacers 28, a part of the gate insulating film 26 corresponding to the space between the gate electrode pattern/sacrificial pattern deposits 44 is selectively removed by properly regulating an ending point of the etching process, thereby inducing the source diffusion layer 24 and the channel diffusion layer 22 (it is an area in which a resistance drop-inducing layer will be formed) to be easily exposed to an exterior, simultaneously with the formation of each insulation spacers 28.

When the formation of the insulation spacers on the both side walls of the gate electrode pattern/sacrificial film pattern deposits 44 is completed through the above-mentioned processes, as shown in FIG. 8, a high concentration of impurities, for example, a high concentration of P-type impurities having a dosage of about 4.9E15(atoms/cm²)˜5.1E15(atoms/cm²) are selectively ion-implanted with 75 KeV˜85 KeV in the channel diffusion layer 22 (it is an area in which a resistance drop-inducing layer will be formed) exposed by the insulation spacers 28, thereby forming a resistance drop-inducing layer 23 which electrically contacts to each source diffusion layers 24 and is located in the channel diffusion layer 22. In this case, the resistance drop-inducing layer 23 flexibly performs functions of dropping a resistance of the metal electrode 29 electrically contacting to the resistance drop-inducing layer and inducing smooth operating characteristics to be shown when the device performs an off operation, as described above.

At this time, as described above, the insulation spacers 28 selectively exposing an expected area in a self-alignment manner, in which the resistance drop-inducing layer 23 will be formed, have been already formed on the semiconductor substrate 21. Thus, a manufacturer can easily avoid a use of a separate mask even when forming the resistance drop-inducing layer 23. Accordingly, it is possible to effectively eliminate various difficulties caused due to a use of the mask.

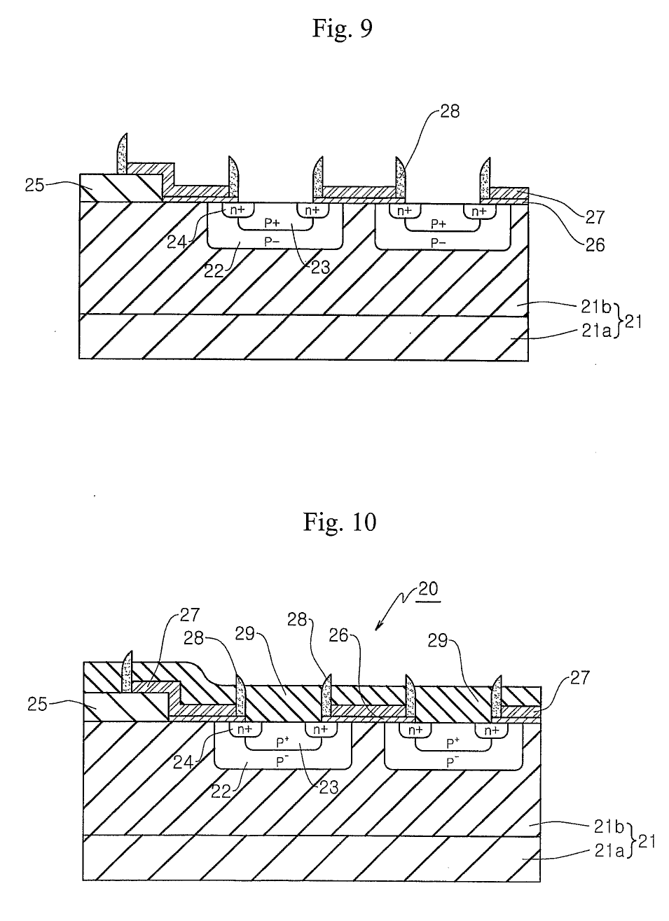

When the formations of the gate electrode pattern/sacrificial film pattern deposits 44, the channel diffusion layer 22, the source diffusion layer 24 and the resistance drop-inducing layer 23, etc. on the active area are completed through the above-mentioned processes, as shown in FIG. 9, the sacrificial film pattern 43 is selectively removed from the gate electrode pattern/sacrificial film pattern deposits 44 through a series of wet-etching process using an etching solution, thereby inducing each of the insulation spacers 28 to be naturally protruded from the gate electrode pattern 27 upward.

Continuously, as shown in FIG. 10, a metal layer is formed on the semiconductor substrate 21 through a series of deposition processes and then is allowed to slowly reflow through a reflow process until the insulation spacers 28 are exposed, thereby forming metal electrodes 29 on the semiconductor substrate 21 which are electrically divided by the insulation spacers 28 and electrically contacts to the source diffusion layer 24 and the resistance drop-inducing layer 23. In this case, a series of metal etch-back processes may be further performed as necessary.

The metal electrode may be formed through a metal flow process of depositing a metal layer and progressing a flow process at the same time.

At this time, the insulation spacers 28, which selectively opens the source diffusion layer 24 and the resistance drop-inducing layer 23 except an area for forming the gate electrode pattern 27 by a self-alignment maimer similarly to the existing contact hole, have been already formed on the semiconductor substrate 21. Thus, a manufacturer can electrically connect the metal electrode 29 to the source diffusion layer 24 and the resistance drop-inducing layer 23 normally, without a separate mask for forming the contact hole. Accordingly, the manufacturer can effectively remove a necessity of the mask for forming the contact hole.

In addition, the insulation spacer 28 is protruded from the gate electrode pattern 27 upward and electrically divides the metal electrodes 29 like as individual pattern structures. Thus, a manufacturer can normally form the patterned metal electrode 29 without a separate mask for forming the metal electrode 29. Accordingly, the manufacturer can effectively remove a necessity of the mask for patterning the metal electrode 29.

After that, according to the invention, an alloying process for bonding a metal and a silicon, a process of machining a back surface of the substrate, a back surface metal deposition and alloying processes are further performed, thereby finishing an initial process for manufacturing a device having a completed shape.

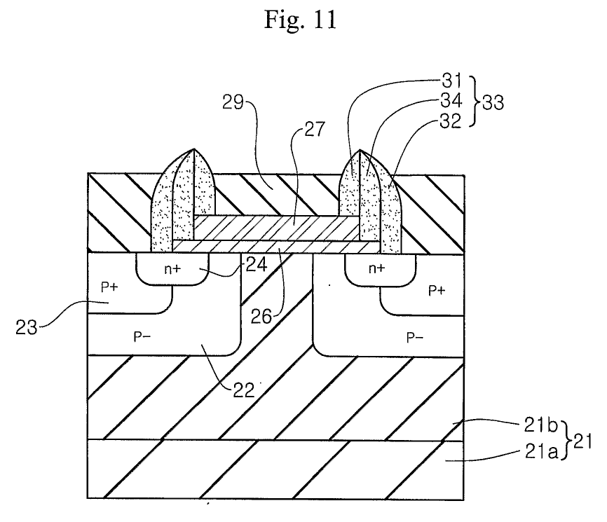

According to another embodiment of the invention as shown in FIG. 11, the insulation spacer may comprise, for example, a core spacer 34 and side spacers 31, 32 covering both sides of the core spacer 34. In this case, each of the insulation spacers 33 preferably maintains its thickness of about 6,000 Å˜36,000 Å.

As such, according to the another embodiment of the invention, when the insulation spacer 33 consists of the core spacer 34 and the side spacers 31, 32 and thus a thickness thereof is increased, the insulation spacer 33 has an improved insulation characteristic as an increase of the thickness thereof. Accordingly, the metal electrodes 29 which are electrically divided by the insulation spacers 33 can maintain a more stable characteristic.

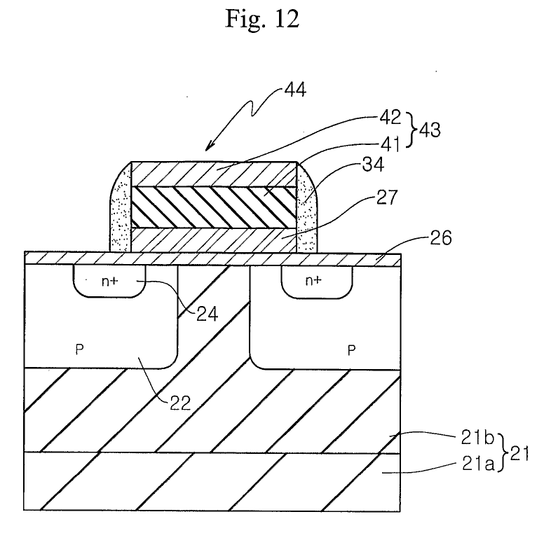

According to the another embodiment of the invention, when the formations of the gate electrode pattern/sacrificial film pattern deposits 44, the channel diffusion layer 22 and the source diffusion layer 24, etc. in the active area of the semiconductor substrate 21 are completed, as shown in FIG. 12, an insulation film, for example, an oxide film having a thickness of about 2,000 Å˜14,000 Å is deposited on the semiconductor substrate comprising the gate electrode pattern/sacrificial film pattern deposits 44 through a series of deposition processes and then anisotropically etched, thereby forming the core spacers 34 on both side walls of each gate electrode pattern/sacrificial film pattern deposits 44. In this case, the core spacer 34 preferably maintains its thickness of 1,000 Å˜12,000 Å.

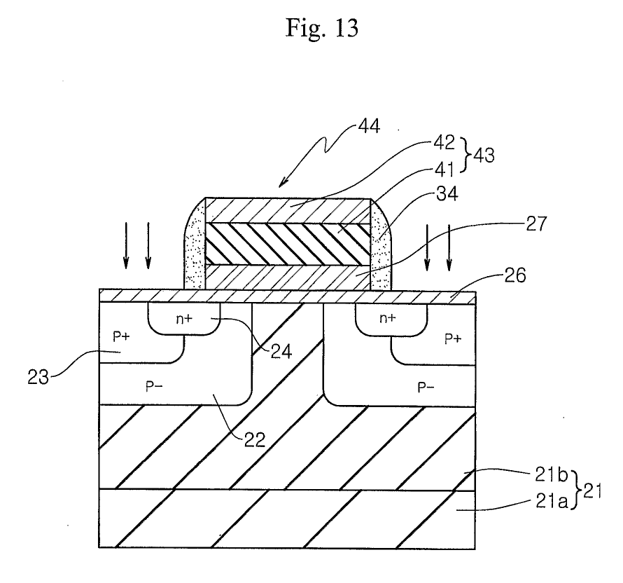

Then, as shown in FIG. 13, a high concentration of impurities, for example, a high concentration of P-type impurities having a dosage of about 4.9E15(atoms/cm²)˜5.1E15(atoms/cm²) are selectively ion-implanted with 75 KeV˜85 KeV in the channel diffusion layer 22 (it is an area in which a resistance drop-inducing layer will be formed) exposed by the core spacers 34, thereby forming a resistance drop-inducing layer 23 which electrically contacts to each source diffusion layers 24 and is located in the channel diffusion layer 22.

At this time, as described above, the core spacers 34 selectively exposing an expected area in a self-alignment manner, in which the resistance drop-inducing layer 23 will be formed, have been already formed on the semiconductor substrate 21. Thus, a manufacturer can easily avoid a use of a separate mask even when forming the resistance drop-inducing layer 23. Accordingly, it is possible to effectively eliminate various difficulties caused due to a use of the mask.

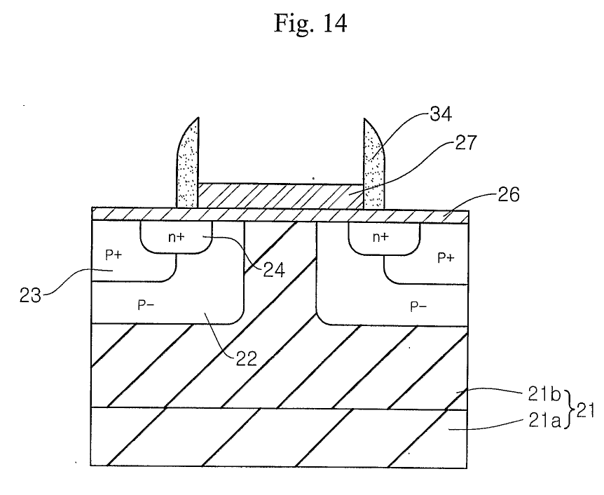

Continuously, as shown in FIG. 14, the sacrificial film pattern 43 is selectively removed from the gate electrode pattern/sacrificial film pattern deposits 44 through a series of wet-etching process using an etching solution, thereby inducing each of the core spacers 28 to be naturally protruded from the gate electrode pattern 27 upward.

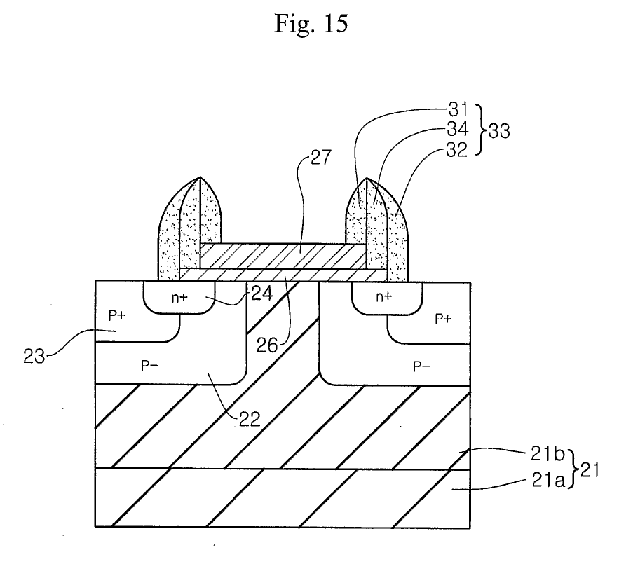

Subsequently, an insulation film, for example, an oxide film having a thickness of 2,000 Å˜14,000 Å is further deposited on the semiconductor substrate 21 comprising the core spacers 34. Then, the oxide film is anisotropically etched, thereby forming side spacers 31,32 on both sides of each core spacers 34 as shown in FIG. 15. In this case, each of the side spacers 31,32 preferably maintain its thickness of 1,000 Å˜12,000 Å.

When forming the side spacers 31,32, a part of the gate insulating film 26 corresponding to the space between the gate electrode patterns 27 is selectively removed by properly regulating an ending point of the etching process, thereby inducing the source diffusion layer 24 and the resistance drop-inducing layer 23 to be easily exposed to an exterior, simultaneously with the formation of the side spacer 32.

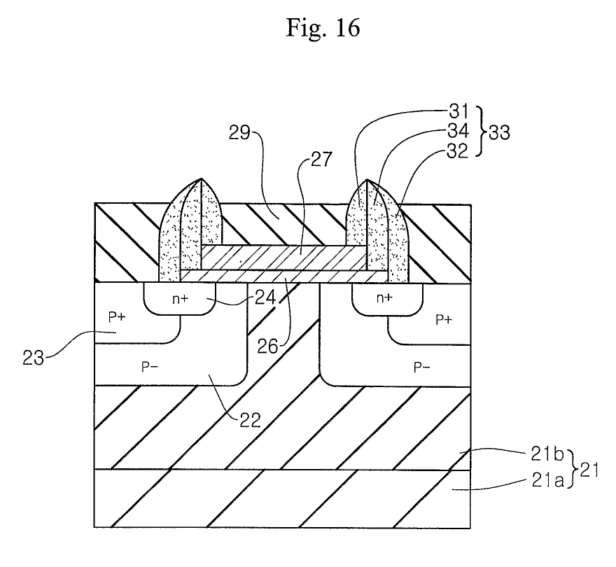

When the outward exposes of the source diffusion layer 24 and the resistance drop-inducing layer 23 are completed through the above processes, as shown in FIG. 16, a metal layer is formed on the semiconductor substrate 21 through a series of deposition processes and then is allowed to slowly reflow through a reflow process until the insulation spacers 33 are exposed, thereby forming metal electrodes 29 on the semiconductor substrate 21 which are electrically divided by the insulation spacers 33 and electrically contacts to the source diffusion layer 24 and the resistance drop-inducing layer 23. In this case, a series of metal etch-back processes may be also further performed as necessary.

Of course, as described above, the metal electrode may be formed through a metal flow process of depositing a metal layer and progressing a flow process at the same time.

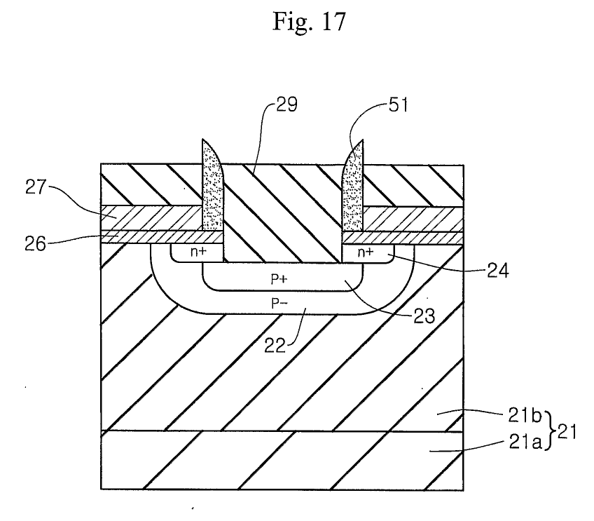

According to a still another embodiment of the invention as shown in FIG. 17, insulation spacers 51 can serve to induce the source diffusion layer 24 to be divided into two areas spaced apart simultaneously with the formation of the insulation spacer, contrary to the above embodiment.

In this case, a manufacturer can naturally spacedly arrange the source diffusion layers 24 in the channel diffusion layer 22 without additionally using the photoresist pattern (PR) as shown in FIG. 6. Accordingly, it is possible to normally form the completed source diffusion layers 24 without a separate mask for spacedly arranging the source diffusion layers 24. As a result, a manufacturer can effectively avoid uses of a mask for spacing the source diffusion layer 24 as well as a mask for forming the resistance drop-inducing layer 23, a mask for forming a contact hole and a mask for patterning the metal electrode 29.

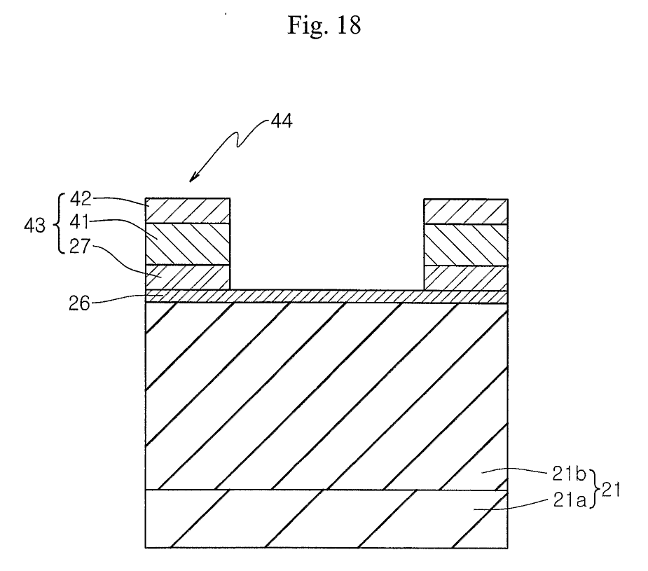

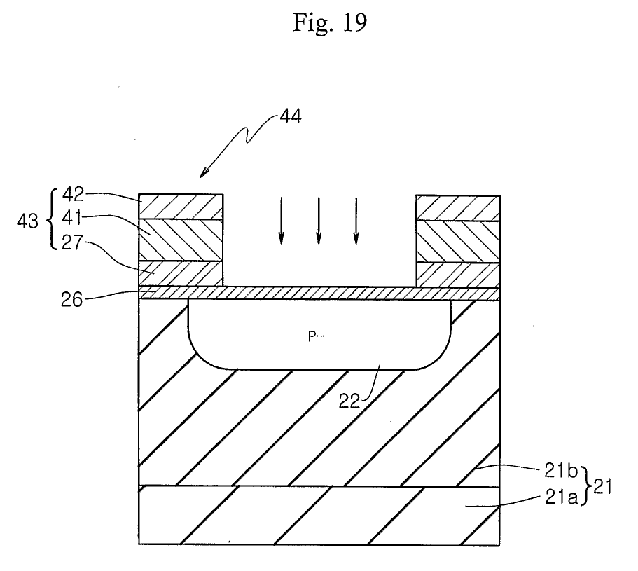

According to still another embodiment of the invention as shown in FIG. 18, when the formations of the gate insulating film 26, and the gate electrode pattern/sacrificial film pattern deposits 44, etc. in the active area of the semiconductor substrate 21 are completed through the above-mentioned processes, as shown in FIG. 19, a low concentration of impurities, for example, a low concentration of P-type impurities are ion-implanted and then driven-in for 30 minutes˜600 minutes under circumstances of 1,000° C.˜1,250° C., thereby forming the channel diffusion layer 22 in a part under the space between the gate electrode pattern/sacrificial film deposits 44.

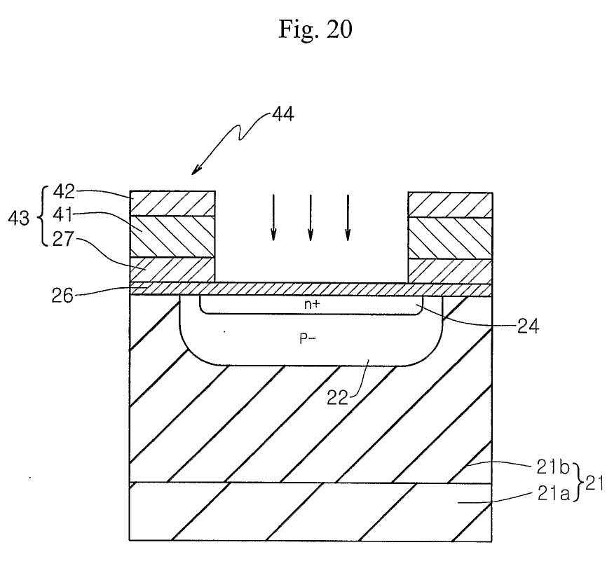

Then, as shown in FIG. 20, a high concentration of impurities, for example, a high concentration of N-type impurities having a dosage of about 4.9E15(atoms/cm²)˜5.1E15(atoms/cm²) are selectively ion-implanted with 75 KeV˜85 KeV on both sides of the gate electrode pattern/sacrificial film deposits 44, thereby forming the source diffusion layer 24 which is located in the channel diffusion layer 22.

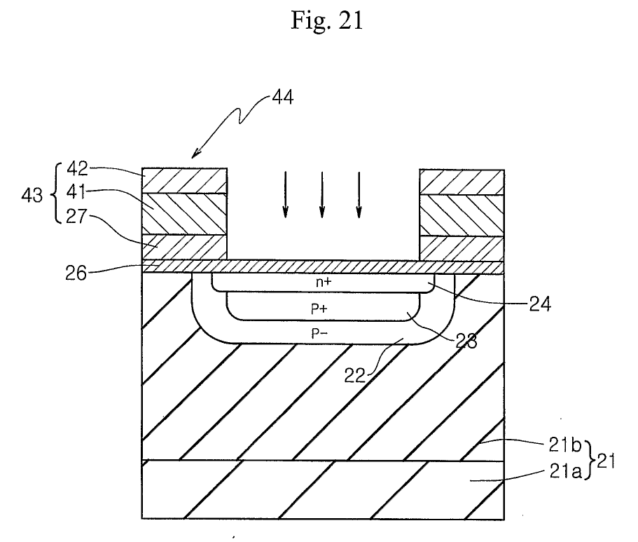

After that, as shown in FIG. 21, a high concentration of impurities, for example, a high concentration of P-type impurities are selectively ion-implanted in the channel diffusion layer 22 (it is an area in which a resistance drop-inducing layer will be formed) with an energy higher than the energy in the case of forming the source diffusion layer 24, thereby forming the resistance drop-inducing layer 23 which electrically contacts to a bottom of the source diffusion layer 24 and is located in the channel diffusion layer 22.

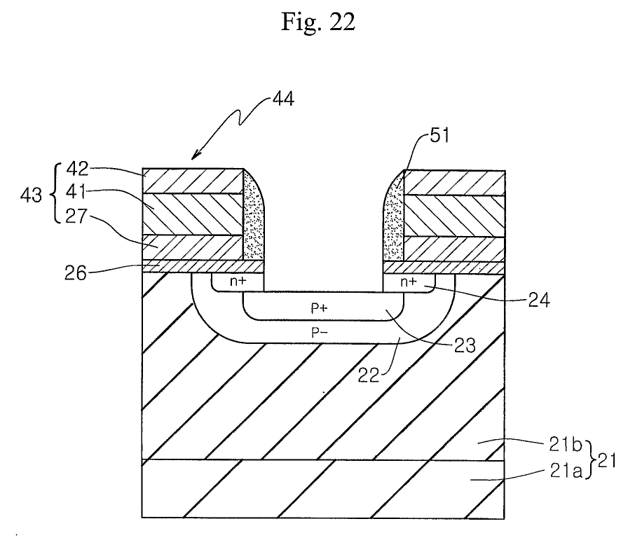

When the formations of the gate electrode pattern/sacrificial film pattern deposits 44, the channel diffusion layer 22, the source diffusion layer 24 and the resistance drop-inducing layer 23, etc. in the active area of the semiconductor substrate are completed through the above-mentioned processes, an insulation film, for example, an oxide film having a thickness of 2,000 Å˜14,000 Å is deposited on the semiconductor substrate comprising the gate electrode pattern/sacrificial film pattern deposits 44 through a series of deposition processes. Then, the oxide film is anisotropically etched, thereby forming insulation spacers 51 on both side walls of each gate electrode pattern/sacrificial pattern deposits 44 as shown in FIG. 22. In this case, the insulation spacer 51 preferably maintains its thickness of 1,000 Å˜12,000 Å.

According to the another embodiment of the invention, when forming the insulation spacers 51, a part of the gate insulating film 26 and a part of the source diffusion layer 24 corresponding to the space between the gate electrode pattern/sacrificial pattern deposits 44 are selectively removed by properly regulating an ending point of the etching process as described above, thereby inducing the source diffusion layer 24 to be divided into two spaced areas and the resistance drop-inducing layer 23 to be easily exposed to an exterior, simultaneously with the formation of each insulation spacers 51.

Of course, when the source diffusion layer 24 is divided into two spaced areas simultaneously with the formation of each insulation spacers 51, a manufacturer can normally obtain the source diffusion layer 24 having a completed shape without a separate mask for spacing the source diffusion layer 24.

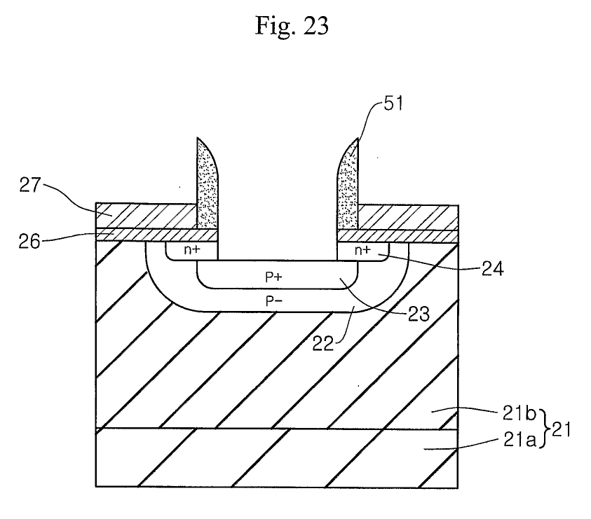

Continuously, as shown in FIG. 23, the sacrificial film pattern 43 is selectively removed from the gate electrode pattern/sacrificial film pattern deposits 44 through a series of wet-etching processes using an etching solution, thereby inducing each of the insulation spacers 51 to be naturally protruded from the gate electrode pattern 27 upward.

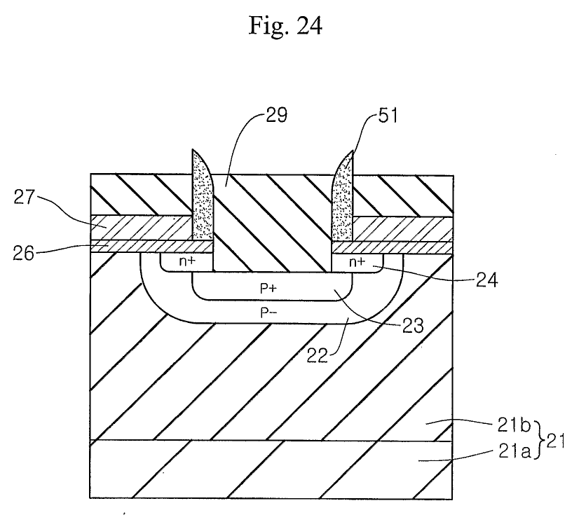

After that, as shown in FIG. 24, a metal layer is formed on the semiconductor substrate 21 through a series of deposition processes and then is allowed to slowly reflow through a reflow process until the insulation spacers are exposed, thereby forming a metal electrode 29 on the semiconductor substrate 21 which is electrically divided by the insulation spacers 51 and electrically contacts to the source diffusion layer 24 and the resistance drop-inducing layer 23. In this case, a series of metal etch-back processes may be also further performed as necessary.

As described above, the metal electrode may be formed through a metal flow process of depositing a metal layer and progressing a flow process at the same time according to the conditions.

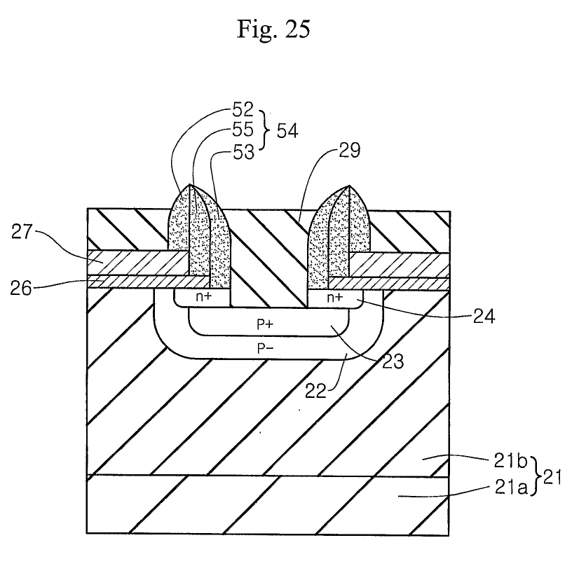

According to another embodiment of the invention as shown in FIG. 25, the insulation spacer may comprise, for example, a core spacer 55 and side spacers 52, 53 covering both sides of the core spacer 55. In this case, the insulation spacer 54 preferably maintains its thickness of 6,000 Å˜36,000 Å.

As such, when the insulation spacer 54 consists of the core spacer 55 and the side spacers 51, 52 and thus a thickness thereof is increased, the insulation spacer 54 can provide an improved insulation characteristic as an increase of the thickness thereof. Accordingly, each of the metal electrodes 29 which are electrically divided by the insulation spacers 54 can maintain a more stable characteristic.

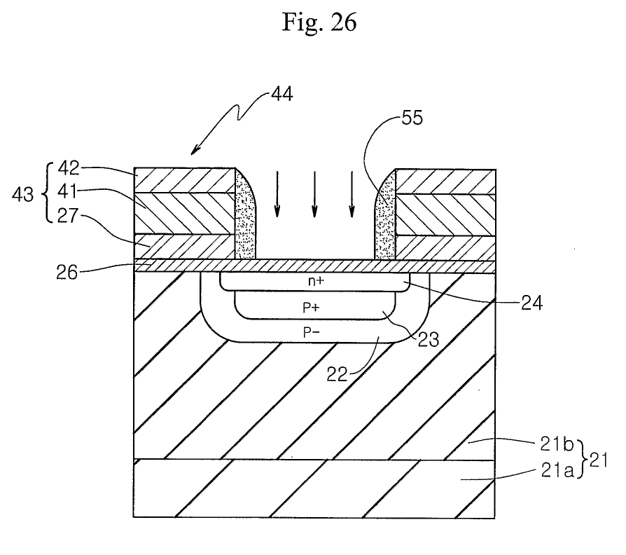

According to the another embodiment of the invention, when the formations of the gate electrode pattern/sacrificial film pattern deposits 44, the channel diffusion layer 22, the source diffusion layer 24 and the resistance drop-inducing layer 23, etc. in the active area of the semiconductor substrate are completed through the above-mentioned processes, as shown in FIG. 26, an insulation film, for example, an oxide film having a thickness of about 2,000 Å˜14,000 Å is deposited on the semiconductor substrate 21 comprising the gate electrode pattern/sacrificial film pattern deposits 44 through a series of deposition processes. Then, the oxide film is anisotropically etched, thereby forming core spacers 55 on both side walls of each gate electrode pattern/sacrificial pattern deposits 44. In this case, the core spacer 55 preferably maintains its thickness of 1,000 Å˜12,000 Å.

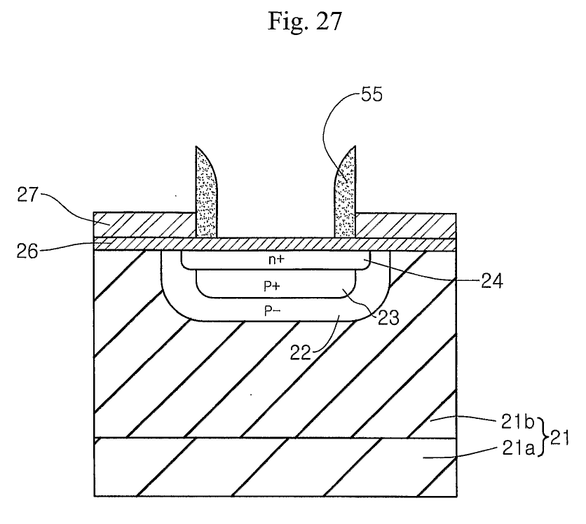

Then, as shown in FIG. 27, the sacrificial film pattern 43 is selectively removed from the gate electrode pattern/sacrificial film pattern deposits 44 through a series of wet-etching process using an etching solution, thereby inducing each of the core spacers 55 to be naturally protruded from the gate electrode pattern 27 upward.

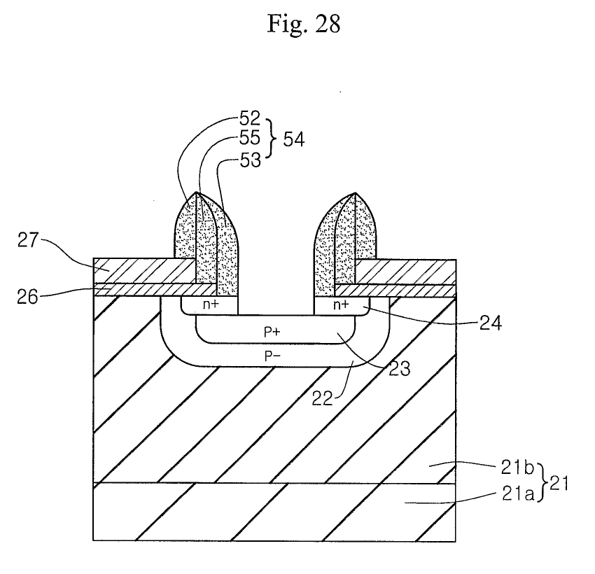

Subsequently, an insulation film, for example, an oxide film having a thickness of about 2,000 Å˜14,000 Å is further deposited on the semiconductor substrate 21 comprising the core spacer 55 through a series of deposition processes. Then, the oxide film is anisotropically etched, thereby forming side spacers 52,53 on both side walls of each core spacers 55 as shown in FIG. 28. In this case, each of the side spacers 52,53 preferably maintains its thickness of 1,000 Å·12,000 Å.

When forming the side spacers 52,53, a part of the gate insulating film 26 and a part of the source diffusion layer 24 corresponding to the space between the gate electrode patterns 27 are selectively removed by properly regulating an ending point of the etching process, thereby inducing the source diffusion layer 24 to be divided into two spaced areas and the resistance drop-inducing layer 23 to be easily exposed to an exterior, simultaneously with the formation of the side spacer 53.

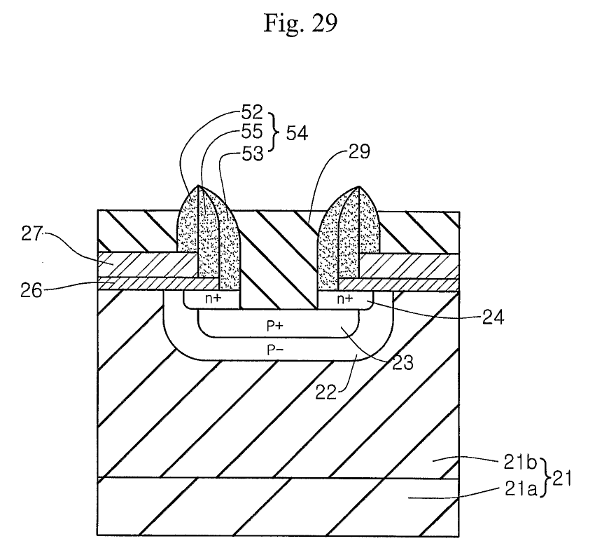

After that, as shown in FIG. 29, a metal layer is formed on the semiconductor substrate 21 through a series of deposition processes and then is allowed to slowly reflow through a reflow process until the insulation spacers 54 are exposed, thereby forming metal electrode 29 on the semiconductor substrate 21, which is electrically divided by the insulation spacers 54 and electrically contacts to the source diffusion layer 24 and the resistance drop-inducing layer 23. In this case, a series of metal etch-back processes may be also further performed as necessary.

Of course, as described above, the metal electrode may be formed through a metal flow process of depositing a metal layer and progressing a flow process at the same time, according to the conditions.

After that, according to the invention, an alloying process for bonding a metal and a silicon, a process of machining a back surface of the substrate, a back surface metal deposition and alloying processes are further performed, thereby finishing an initial process for manufacturing a device having a completed shape.

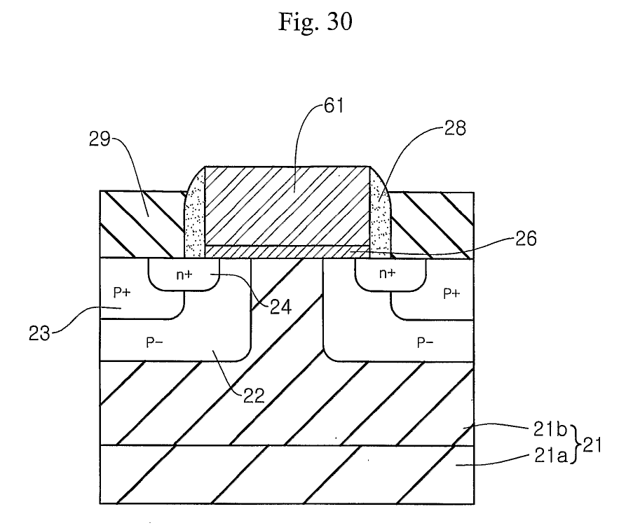

On the other hand, according to another embodiment of the invention as shown in FIG. 30, the insulation spacers 28 may be formed, based on a gate electrode pattern 61 only, without depending on the sacrificial film pattern. In this case, each of the gate electrode patterns 61 is spacedly arranged in the active area of the semiconductor substrate 21 and preferably has an increased thickness of 9,000 Å˜38,000 Å, compared to the above embodiments (and the prior art).

Of course, when the insulation spacers 28 may be formed, based on the gate electrode pattern 61 only, without depending on the sacrificial film pattern, a manufacturer can eliminate the processes of forming and removing the sacrificial film pattern at ease and obtain an improved process efficiency.

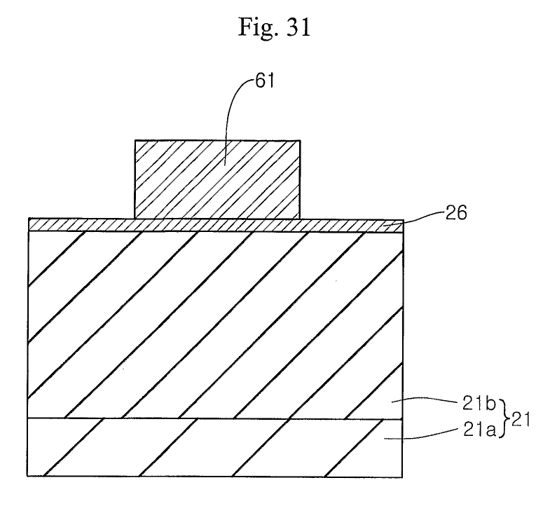

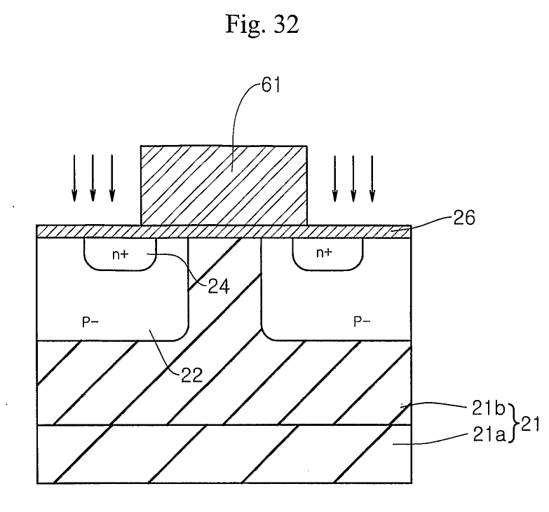

According to the another embodiment of the invention, when the formation of the gate insulating film 26 in the active area of the semiconductor substrate 21 is completed through the above-mentioned processes as shown in FIG. 31, a plurality of gate electrode patterns having an increased thickness of 9,000 Å˜38,000 Å are individually spacedly formed on the gate insulating film 26 through a series of deposition and patterning processes.

After that, as shown in FIG. 32, the channel diffusion layer and the source diffusion layer, etc. are further formed in the active area of the semiconductor substrate 21 through a series of ion implantation and photoresist patterning processes.

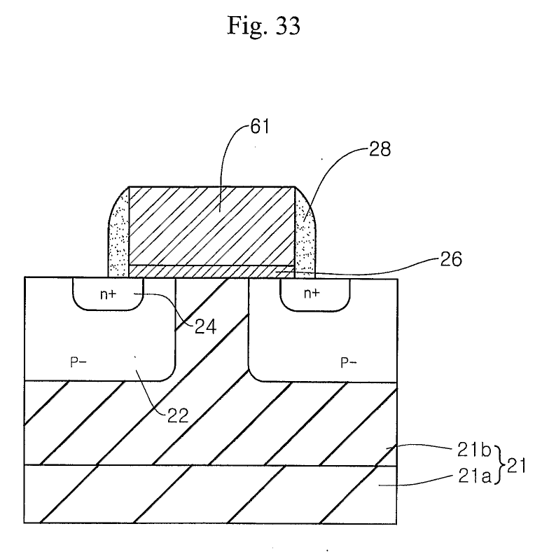

Subsequently, an insulation film, for example, an oxide film having a thickness of about 2,000 Å˜14,000 Å is deposited on the semiconductor substrate 21 comprising the gate electrode pattern 61 through a series of deposition processes. Then, the oxide film is anisotropically etched, thereby forming insulation spacers 28 on both side walls of each of the gate electrode patterns 61 as shown in FIG. 33. In this case, each of the insulation spacers 28 preferably maintains its thickness of 1,000 Å˜12,000 Å.

When forming the insulation spacers 28, a part of the gate insulating film 26 corresponding to the space between the gate electrode patterns 61 is selectively removed by properly regulating an ending point of the etching process, thereby inducing the source diffusion layer 24 and the channel diffusion layer 22 (it is an expected area in which a resistance drop-inducing layer will be formed) to be easily exposed to an exterior, simultaneously with the formation of the insulation spacer 28.

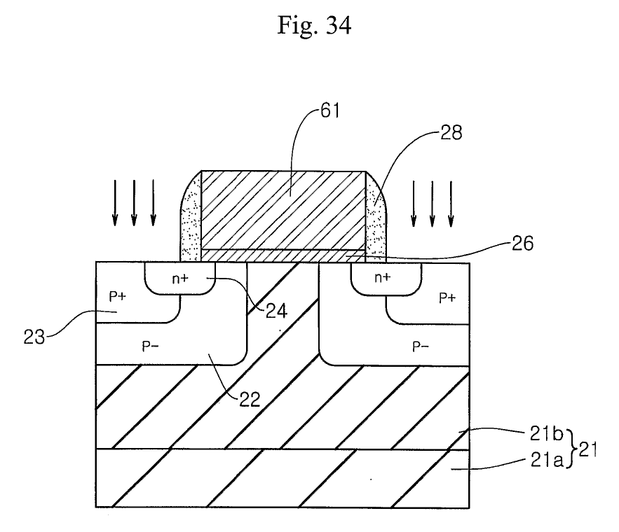

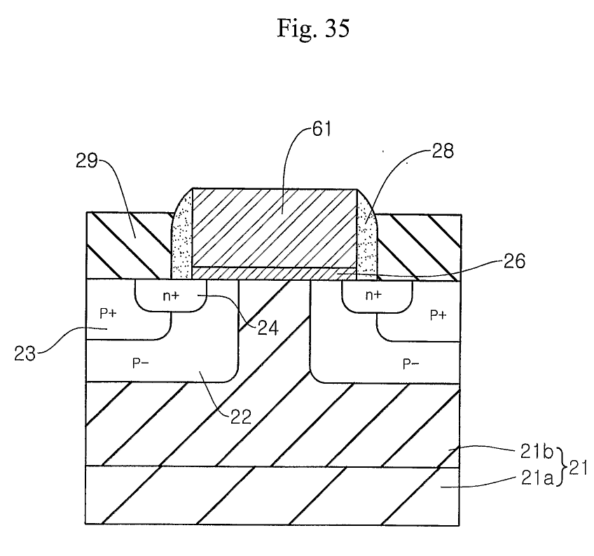

Continuously, as shown in FIG. 34, a high concentration of impurities, for example, a high concentration of P-type impurities having a dosage of about 4.9E15(atoms/cm²)˜5.1E15(atoms/cm²) are selectively ion-implanted with 75 KeV˜85 KeV in the channel diffusion layer 22 (it is an area in which a resistance drop-inducing layer will be formed) exposed by the insulation spacers 28, thereby forming a resistance drop-inducing layer 23 which electrically contacts to each pair of source diffusion layers 24 and is located in the channel diffusion layer 22.

After that, a metal layer is formed on the semiconductor substrate 21 through a series of deposition processes and then is allowed to slowly reflow through a reflow process until the insulation spacers 33 are exposed, thereby forming metal electrodes 29 on the semiconductor substrate 21, which are electrically divided by the insulation spacers 33 and electrically contact to the source diffusion layer 24 and the resistance drop-inducing layer 23. In this case, a series of metal etch-back processes may be also further performed as necessary.

Needless to say, as described above, the metal electrode may be formed through a metal flow process of depositing a metal layer and progressing a flow process at the same time.

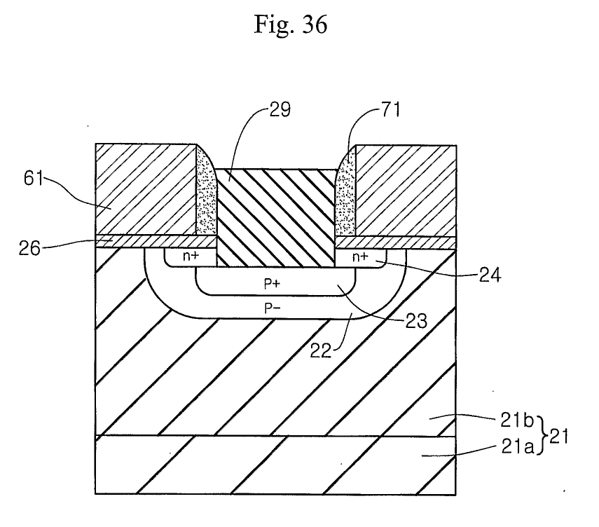

Even when the insulation spacers are formed based on the gate electrode pattern only as shown in FIG. 36, each insulation spacer 71 can perform the function of inducing the source diffusion layer 24 to be divided into the two spaced areas, simultaneously with the formation of the insulation spacer itself.

Of course, in this case, a manufacturer can effectively eliminate a use of the mask for spacing the source diffusion layers 24 as well as inconveniences caused due to the formation and removal of the sacrificial film pattern.

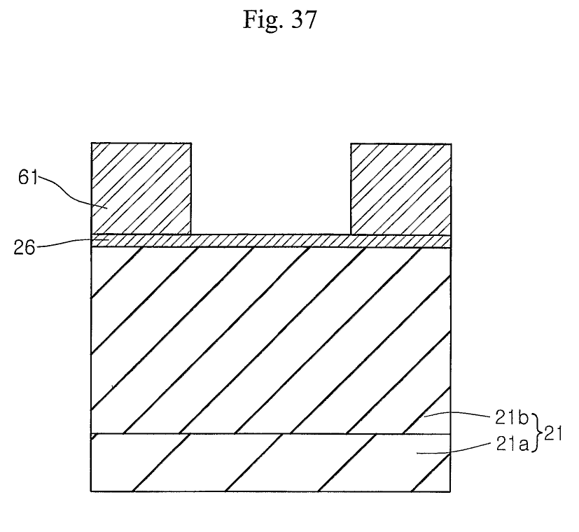

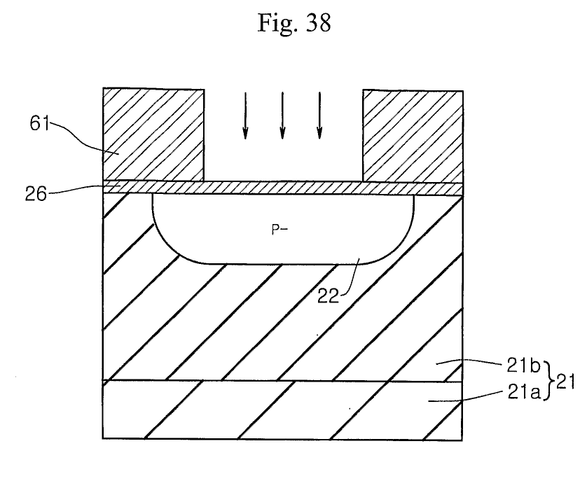

According to the another embodiment of the invention, as shown in FIG. 37, when the formations of the gate insulating film 26, the gate electrode patterns 61, etc. in the active area of the semiconductor substrate 21 are completed through the above-mentioned processes, as shown in FIG. 38, a low concentration of impurities, for example, a low concentration of P-type impurities are ion-implanted and then driven-in for 30 minutes˜600 minutes under circumstances of 1,000° C.˜1,250° C., thereby forming a channel diffusion layer 22 in a part under the space between the gate electrode patterns 61.

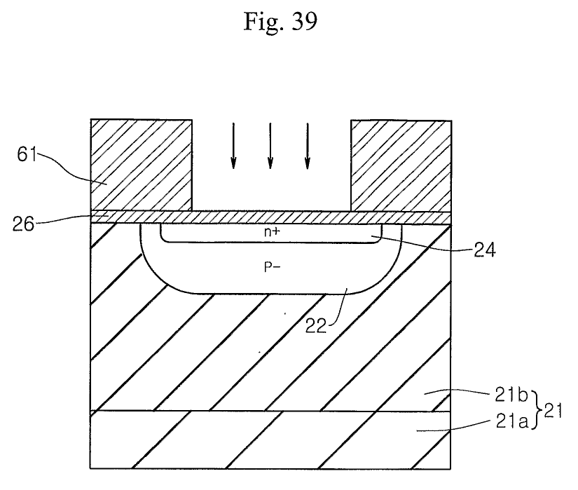

Then, as shown in FIG. 39, a high concentration of impurities, for example, a high concentration of N-type impurities having a dosage of about 4.9E15(atoms/cm²)˜5.1E15(atoms/cm²) are selectively ion-implanted with 75 KeV˜85 KeV in both sides of the gate electrode pattern 61, thereby forming a source diffusion layer 24 located in the channel diffusion layer 22.

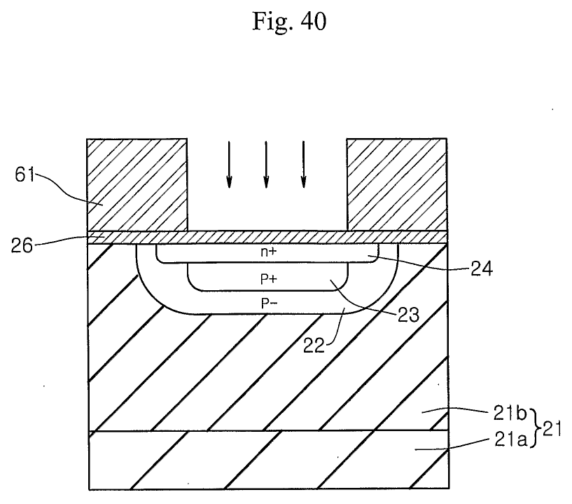

After that, as shown in FIG. 40, a high concentration of impurities, for example, a high concentration of P-type impurities are selectively ion-implanted in the channel diffusion layer 22 (it is an area in which a resistance drop-inducing layer will be formed) with an energy higher than the energy in the case of forming the source diffusion layer 24, thereby forming a resistance drop-inducing layer 23 which electrically contacts to a bottom of the source diffusion layer 24 and is located in the channel diffusion layer 22.

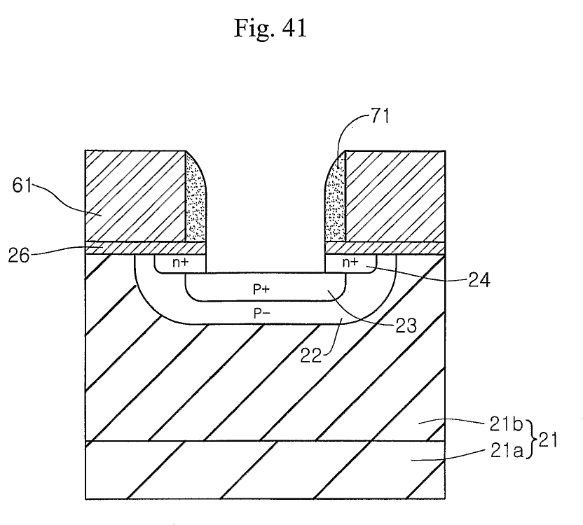

When the formations of the gate electrode patterns 61, the channel diffusion layer 22, the source diffusion layer 24 and the resistance drop-inducing layer 23, etc. in the area of the semiconductor substrate are completed through the above-mentioned processes, an insulation film, for example, an oxide film having a thickness of 2,000 Å˜14,000 Å is deposited on the semiconductor substrate comprising the gate electrode pattern/sacrificial film pattern deposits 44 through a series of deposition processes. Then, the oxide film is anisotropically etched, thereby forming insulation spacers 71 on both side walls of each gate electrode pattern/sacrificial pattern deposits 44, as shown in FIG. 41. In this case, each of the insulation spacer 71 preferably maintains its thickness of 1,000 Å˜12,000 Å.

According to the another embodiment of the invention, when forming the insulation spacers 71, a part of the gate insulating film 26 and a part of the source diffusion layer 24 corresponding to the space between the gate electrode patterns 61 are selectively removed by properly regulating an ending point of the etching process as described above, thereby inducing the source diffusion layer 24 to be divided into two spaced areas and the resistance drop-inducing layer 23 to be easily exposed to an exterior, simultaneously with the formation of each insulation spacers 71.

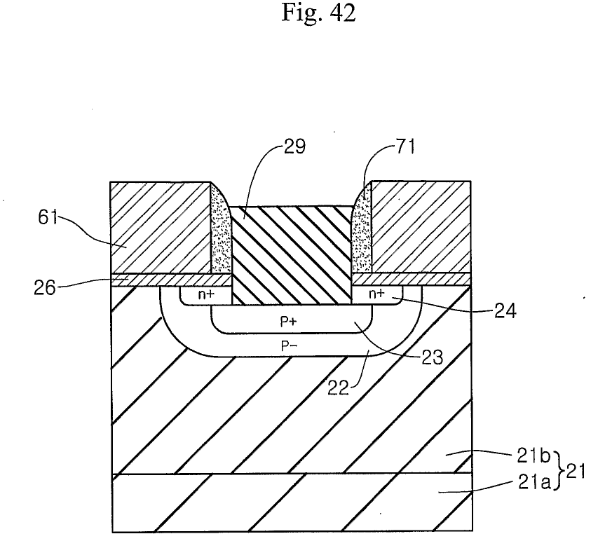

After that, as shown in FIG. 42, a metal layer is formed on the semiconductor substrate 21 through a series of deposition processes and then is allowed to slowly reflow through a reflow process until the insulation spacers 71 are exposed, thereby forming metal electrodes 29 on the semiconductor substrate 21, which are electrically divided by the insulation spacers 71 and electrically contacts to the source diffusion layer 24 and the resistance drop-inducing layer 23. In this case, a series of metal etch-back processes may be also further performed as necessary.

Needless to say, as described above, the metal electrode may be formed through a metal flow process of depositing a metal layer and progressing a flow process at the same time.

In the mean time, the invention may be variously modified according to the conditions.

For example, according to the invention, the metal electrode may be formed through a contact plug process, for instance, a tungsten plug process. Alternatively, the metal electrode may be formed by continuously progressing the tungsten plug process and the metal reflow (flow) process.

Later, according to the invention, an alloying process for bonding a metal and a silicon, a process of machining a back surface of the substrate, a back surface metal deposition and alloying processes are further performed, thereby finishing an initial process for manufacturing a device having a complete shape.

### INDUSTRIAL APPLICABILITY

As described above, according to the invention, an insulation spacer capable of substitute-performing functions of an inter-insulation film, a contact hole and a mask, etc. by a self-alignment and simplifying a general process for manufacturing a device is newly arranged in a part of a gate electrode pattern. Thus, it is possible to naturally reduce the number of masks required for the device manufacture, thereby allowing a manufacturer to easily avoid various problems caused due to an increase of the number of masks, for example, an increase of manufacturing cost, an extension of a manufacturing period, an increase of a burden of stored goods (physical distribution), a falling off in cost competitiveness, and an extension of a product development period, etc.

In addition, according to the invention, an insulation spacer capable of substitute-performing functions of an inter-insulation film, a contact hole and a mask, etc. by a self-alignment is newly arranged and thus the number of masks required for a device manufacture is naturally reduced, so that a morphology abnormality of each unit patterns caused due to a miss-alignment of the mask is minimized. Thus, a size of the device to be finally completed can be effectively reduced.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A high breakdown voltage semiconductor device comprising:
gate electrode patterns individually spacedly formed in an active area of a semiconductor substrate;
a channel diffusion layer selectively occupying a part under the space between the gate electrode patterns;
source diffusion layers located in both sides of each gate electrode patterns and spacedly formed in a pair in the channel diffusion layer;
a resistance drop-inducing layer electrically contacting to each pair of the source diffusion layers located in the channel diffusion layer and selectively arranged in the channel diffusion layer;
insulation spacers selectively covering both side walls of each gate electrode patterns so as to allow a part of the source diffusion layer and a part of the resistance drop-inducing layer to be selectively exposed and protruding from each of the gate electrode patterns upward; and
a metal electrode occupying an upper part of the semiconductor substrate so as to allow each insulation spacers to be exposed, electrically contacting to the source diffusion layer and the resistance drop-inducing layer exposed by the insulation spacer, and electrically divided by the insulation spacers.

2. The high breakdown voltage semiconductor device according to claim 1, wherein each of the insulation spacers consists of a core spacer and side spacers covering both sides of the core spacer.

3. A method of manufacturing a high breakdown voltage semiconductor device comprising steps of:
sequentially depositing a raw material layer of a gate electrode pattern and a sacrificial film on a front surface of a semiconductor substrate having an active area defined, and selectively patterning the raw material layer of the gate electrode pattern and the sacrificial film to form a plurality of gate electrode pattern/sacrificial film pattern deposits individually spaced in the active area;
selectively ion-implanting first conductive impurities in the active area to form a channel diffusion layer in a part under the space between the gate electrode pattern/sacrificial film pattern deposits;
selectively ion-implanting second conductive impurities in both sides of the gate electrode pattern/sacrificial film pattern deposits to form a pair of source diffusion layers spaced in the channel diffusion layer;
forming insulation spacers on both side walls of the gate electrode pattern/sacrificial film pattern deposits so as to allow the channel diffusion layer and the source diffusion layers to be selectively exposed;
selectively ion-implanting the first conductive impurities using the insulation spacers as a mask to form a resistance drop-inducing layer electrically contacting to the pair of source diffusion layers and located in the channel diffusion layer;
selectively removing the sacrificial film pattern from the gate electrode pattern/sacrificial film pattern deposits so as to allow the insulation spacers to protrude from the gate electrode pattern upward; and
forming a metal electrode, which is electrically divided by the insulation spacers and electrically contacts to the source diffusion layer and the resistance drop-inducing layer, on an upper part of the semiconductor substrate.

4. A method of manufacturing a high breakdown voltage semiconductor device comprising steps of:
sequentially depositing a raw material layer of a gate electrode pattern and a sacrificial film on a front surface of a semiconductor substrate having an active area defined, and selectively patterning the raw material layer of the gate electrode pattern and the sacrificial film to form a plurality of gate electrode pattern/sacrificial film pattern deposits individually spaced in the active area;
selectively ion-implanting first conductive impurities in the active area to form a channel diffusion layer in a part under the space between the gate electrode pattern/sacrificial film pattern deposits;
selectively ion-implanting second conductive impurities in both sides of the gate electrode pattern/sacrificial film pattern deposits to form a source diffusion layer located in the channel diffusion layer;
selectively ion-implanting the first conductive impurities in the channel diffusion layer to form a resistance drop-inducing layer electrically contacting to a bottom of the source diffusion layer and located in the channel diffusion layer;
forming insulation spacers on both side walls of the gate electrode pattern/sacrificial film pattern deposits so as to allow the source diffusion layer to be divided into two spaced areas and the resistance drop-inducing layer to be selectively exposed; selectively removing the sacrificial film pattern from the gate electrode pattern/sacrificial film pattern deposits so as to allow the insulation spacers to protrude from the gate electrode pattern upward; and
forming a metal electrode, which is electrically divided by the insulation spacers and electrically contacts to the source diffusion layer and the resistance drop-inducing layer, on an upper part of the semiconductor substrate.

5. A method of manufacturing a high breakdown voltage semiconductor device comprising steps of:
forming a plurality of gate electrode patterns, which are individually spaced and have a substantially increased thickness, in an upper part of an active area of a semiconductor substrate;
selectively ion-implanting first conductive impurities in the active area to form a channel diffusion layer in a part under the space between the gate electrode patterns;
selectively ion-implanting second conductive impurities in both sides of the gate electrode patterns to form a pair of channel diffusion layers spaced in the channel diffusion layer;
forming insulation spacers on both side walls of each of the gate electrode patterns so as to allow the channel diffusion layer and the source diffusion layers to be selectively exposed;
selectively ion-implanting the first conductive impurities using the insulation spacers as a mask to form a resistance drop-inducing layer electrically contacting to the source diffusion layers and located in the channel diffusion layer; and
forming a metal electrode, which is electrically divided by the insulation spacers and electrically contacts to the source diffusion layer and the resistance drop-inducing layer, on an upper part of the semiconductor substrate.

6. A method of manufacturing a high breakdown voltage semiconductor device comprising steps of:
forming a plurality of gate electrode patterns, which are individually spaced and have a substantially increased thickness, in an upper part of an active area of a semiconductor substrate;
selectively ion-implanting first conductive impurities in the active area to form a channel diffusion layer in a part under the space between the gate electrode patterns;
selectively ion-implanting second conductive impurities in both sides of the gate electrode patterns to form a source diffusion layer located in the channel diffusion layer;
selectively ion-implanting the first conductive impurities in the channel diffusion layer to form a resistance drop-inducing layer electrically contacting to a bottom of the source diffusion layer and located in the channel diffusion layer;
forming insulation spacers on both side walls of the gate electrode pattern/sacrificial film pattern deposits so as to allow the source diffusion layer to be divided into two spaced areas and the resistance drop-inducing layer to be selectively exposed; and
forming a metal electrode, which is electrically divided by the insulation spacers and electrically contacts to the source diffusion layer and the resistance drop-inducing layer, on an upper part of the semiconductor substrate.

7. The method of manufacturing a high breakdown voltage semiconductor device according to claim 3 or 4, wherein the sacrificial film pattern has a thickness of 5,000 Å˜30,000 Å.

8. The method of manufacturing a high breakdown voltage semiconductor device according to any one of claims 3 to 6, wherein the insulation spacer has a thickness of 1,000 Å˜12,000 Å

9. The method of manufacturing a high breakdown voltage semiconductor device according to any one of claims 3 to 6, wherein the metal electrode is formed through a metal flow process or metal reflow process.
